(19) United States
(12) Patent Application Publication
(10) Pub. No.: US 2004/0148772 A1
(43) Pub. Date: Aug. 5, 2004

(54) Method for packaging an injection-molded image sensor

(76) Inventors: Jackson Hsieh, Hsinchu Hsien (TW); Jichen Wu, Hsinchu Hsien (TW)

Correspondence Address: PRO-TECHTOR INTERNATIONAL, 20775 Norada Court, Saratoga, CA, 95070-3018, US

(21) Appl. No.: 10/358,483

(22) Filed: Feb. 4, 2003

(51) Int. Cl. H05K 3/30

(52) U.S. Cl. 29/855; 29/832

(57) ABSTRACT

A method for packaging an injection-molded image sensor includes the steps of: providing metal sheets arranged in a matrix, each of the metal sheets having a first board, a second board and a third board to form a [symbol] -shaped structure; performing a first injection molding process to encapsulate the metal sheets and to form a first molded body with the first to third boards exposed; performing a second injection molding process to form a second molded body and a cavity on the first molded body, wherein the first boards are located within the cavity; arranging a photosensitive chip having bonding pads within the cavity; providing wires for electrically connecting the bonding pads to the first boards, respectively; and arranging a transparent layer on a top of the second molded body to cover over the photosensitive chip.

### BACKGROUND OF THE INVENTION

1. Field of the Invention

The invention relates to a method for packaging an injection-molded image sensor, and in particular to a method for packaging an image sensor by way of injection molding.

2. Description of the Related Art

A general sensor is used for sensing signals, which may be optical or audio signals. The sensor of the invention is used to receive image signals or optical signals. After receiving image signals, the sensor converts the image signals into electrical signals, which are then transmitted to a printed circuit board via a substrate.

Referring to FIG. 1, a conventional image sensor includes a substrate 10, a frame layer 12, a photosensitive chip 14, a plurality of wires 15, and a transparent layer 22. The substrate 10 has an upper surface 11 on which signal input terminals 18 are formed, and a lower surface 13 on which signal output terminals 24 are formed. The frame layer 12 is arranged on the substrate 10 to form a cavity 16 together with the substrate 10. The photosensitive chip 14 is arranged on the substrate 10 and within the cavity 16. A plurality of bonding pads 20 is formed on the photosensitive chip 14. The wires 15 electrically connect the bonding pads 20 of the photosensitive chip 14 to the signal input terminals 18 of the substrate 10, respectively. The transparent layer 22 is coated with an adhesive layer 23 and arranged on the frame layer 12 to cover and encapsulate the photosensitive chip 14.

The method for packaging the image sensor has the following drawbacks.

1. The image sensor has to be manufactured individually and cannot be manufactured in mass production, so the manufacturing cost cannot be effectively lowered.

2. During the packaging process, a substrate 10 has to be provided for each package body, and then a frame layer 12 is adhered to the substrate 10. Therefore, the manufacturing processes are inconvenient, the material cost is increased, and the overflowing adhesive during the adhesive applying process may influence the wire bonding process.

### SUMMARY OF THE INVENTION

An object of the invention is to provide a method for packaging an injection-molded image sensor in mass production by way of injection molding so as to reduce the manufacturing cost.

Another object of the invention is to provide a method for packaging an injection-molded image sensor by way of injection molding to form the package structure and prevent overflowing adhesive from influencing the wire bonding process.

Still another of the invention is to provide a method for packaging an injection-molded image sensor, in which metal sheets are used instead of the substrate and traces thereon so that the material and manufacturing costs may be effectively lowered.

To achieve the above-mentioned objects, the invention provides a method for packaging an injection-molded image sensor. The method includes the steps of:

providing a plurality of metal sheets arranged in a matrix, each of the metal sheets having a first board, a second board and a third board to form a [symbol] -shaped structure;

performing a first injection molding process to encapsulate each of the metal sheets and to form a first molded body, wherein the first boards of the metal sheets are exposed from an upper surface of the first molded body, the second boards are exposed from a lower surface of the first molded body, and the third boards are exposed from a lateral surface of the first molded body;

performing a second injection molding process to form a second molded body on the first molded body, wherein the first molded body and the second molded body form a cavity, and the first boards have first connection points located within the cavity;

arranging a photosensitive chip, on which a plurality of bonding pads is formed, within the cavity;

providing a plurality of wires for electrically connecting the bonding pads of the photosensitive chip to the first boards of the metal sheets, respectively; and

arranging a transparent layer on a top of the second molded body to cover over the photosensitive chip.

### BRIEF DESCRIPTION OF THE DRAWINGS

FIG. 1 is a cross-sectional view showing a conventional image sensor.

FIG. 2 is a first schematic illustration showing a method for packaging an injection-molded image sensor of the invention.

FIG. 3 is a second schematic illustration showing the method for packaging the injection-molded image sensor of the invention.

FIG. 4 is a third schematic illustration showing the method for packaging the injection-molded image sensor of the invention.

FIG. 5 is a fourth schematic illustration showing the method for packaging the injection-molded image sensor of the invention.

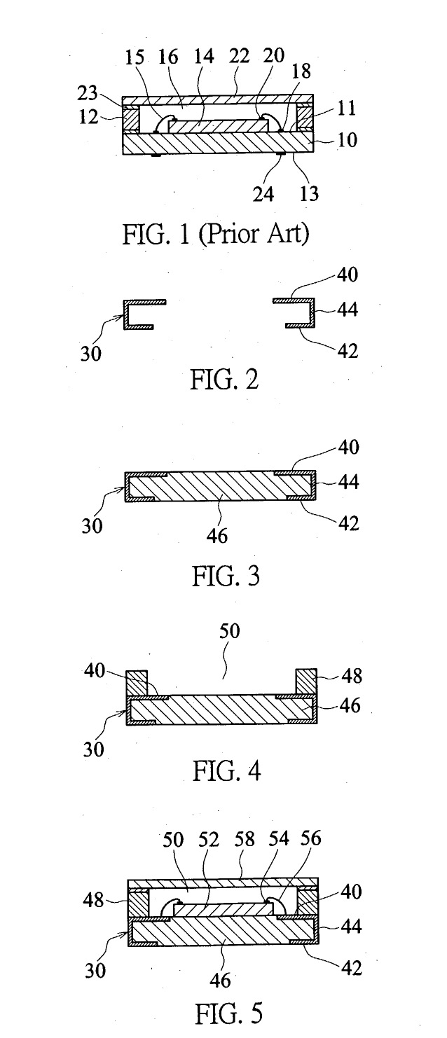

### DETAILED DESCRIPTION OF THE INVENTION

Referring to FIG. 2, a method for packing an injection-molded image sensor includes the following steps.

First, a plurality of metal sheets 30, each of which has a first board 40, a second board 42 and a third board 44 to form a [symbol] -shaped structure, is provided. The metal sheets 30 are arranged in a matrix, and the arrangement is such that the metal sheets 30 form a frame structure having four sides.

Next, please refer to FIG. 3. A first injection molding process is performed to inject an industrial plastic material to mold and encapsulate each metal sheet 30 so that a first molded body 46 is formed. At this state, the first boards 40 of the metal sheets 30 are exposed from an upper surface of the first molded body 46, the second boards 42 are exposed from a lower surface of the first molded body 46, and the third boards 44 are exposed from a lateral surface of the first molded body 46.

Then, please refer to FIG. 4. A second injection molding process is performed to inject an industrial plastic material to form a second molded body 48 on the first molded body 46. The second molded body 48 and the first molded body 46 form a cavity 50, and the first boards 40 of the metal sheets 30 are located within the cavity 50.

Next, please refer to FIG. 5. A photosensitive chip 52, on which a plurality of bonding pads 54 is formed, is arranged within the cavity 50 and mounted to the first molded body 46.

Then, a plurality of wires 56 is provided to electrically connect the bonding pads 54 of the photosensitive chip 52 to the first boards 40 of the metal sheets 30, respectively. Thus, signals from the photosensitive chip 52 may be transferred to the plurality of metal sheets 30.

Next, a transparent layer 58 is mounted to a top of the second molded body 48 to cover over the photosensitive chip 52 so that the photosensitive chip 52 may receive optical signals passing through the transparent layer 58.

The method for packaging the injection-molded image sensor of the invention has the following advantages.

1. Since a lot of image sensors may be manufactured in mass production by way of injection molding, the manufacturing cost of the image sensors may be reduced.

2. Since the package body is formed by way of injection molding, the overflowing adhesive may be avoided.

3. Since the metal sheets 30 are used instead of the substrate and traces thereon, the material and manufacturing costs may be effectively reduced.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A method for packaging an injection-molded image sensor, comprising the steps of:
providing a plurality of metal sheets arranged in a matrix, each of the metal sheets having a first board, a second board and a third board to form a [symbol] -shaped structure;
performing a first injection molding process to encapsulate each of the metal sheets and to form a first molded body, wherein the first boards of the metal sheets are exposed from an upper surface of the first molded body, the second boards are exposed from a lower surface of the first molded body, and the third boards are exposed from a lateral surface of the first molded body;
performing a second injection molding process to form a second molded body on the first molded body, wherein the first molded body and the second molded body form a cavity, and the first boards have first connection points located within the cavity;
arranging a photosensitive chip, on which a plurality of bonding pads is formed, within the cavity;
providing a plurality of wires for electrically connecting the bonding pads of the photosensitive chip to the first boards of the metal sheets, respectively; and
arranging a transparent layer on a top of the second molded body to cover over the photosensitive chip.

2. The method according to claim 1, wherein the first molded body and the second molded body are made of industrial plastic material.

3. The method according to claim 1, wherein the transparent layer is a piece of transparent glass.
